(19) United States
(12) Patent Application Publication
(10) Pub. No.: US 2014/0312733 A1
(43) Pub. Date: Oct. 23, 2014

(54) MEMS VIBRATOR, ELECTRONIC APPARATUS, AND MOVING OBJECT

(71) Applicant: Seiko Epson Corporation, Tokyo (JP)

(72) Inventors: Ryuji KIHARA, Matsumoto (JP); Osamu IWAMOTO, Hara (JP)

(73) Assignee: Seiko Epson Corporation, Tokyo (JP)

(21) Appl. No.: 14/254,259

(22) Filed: Apr. 16, 2014

(30) Foreign Application Priority Data
Apr. 18, 2013 (JP) 2013-087207

(51) Int. Cl. B81B 3/00

(52) U.S. Cl. CPC B81B 3/0097
USPC 310/300

(57) ABSTRACT

A MEMS vibrator includes: a vibrating portion; an electrode portion provided to face the vibrating portion with a gap therebetween; and a support portion extended in a first direction from the vibrating portion. The vibrating portion includes a functional portion having a different thickness viewed from the first direction.

### BACKGROUND

1. Technical Field

The present invention relates to a MEMS vibrator, an electronic apparatus, and a moving object.

2. Related Art

In general, electromechanical system structures (for example, vibrators, filters, sensors, motors, and the like) including a mechanically movable structure, which are formed using a semiconductor microfabrication technique and called micro electro mechanical system (MEMS) devices, have been known. MEMS vibrators of the MEMS devices are easily manufactured incorporating an oscillator circuit or the like and thus advantageous for miniaturization and higher functionality, compared to vibrators and resonators using quartz crystal or a dielectric. Therefore, the scope of application of the MEMS vibrators is expanded.

As a representative example of vibrators in the related art, a beam vibrator that vibrates in a thickness direction of a substrate has been known. The beam vibrator is configured to include a fixed electrode provided on the substrate and a vibrating portion provided with a gap relative to the fixed electrode. As the types of the beam vibrator, a clamped-free beam vibrator, a clamped-clamped beam vibrator, a free-free beam vibrator, and the like have been known, depending on the way of supporting the vibrating portion.

For the beam vibrator, the way of supporting the vibrating portion is selected according to a desired vibration mode. For example, in the vibration mode of the free-free beam vibrator, the free-free beam vibrator desirably performs bending vibration in which the node of vibration is provided in a first direction in which a beam portion is extended from the vibrating portion, the wave of vibration is provided in a second direction intersecting the first direction, and the antinode of vibration is provided in a third direction orthogonal to the first direction and the second direction.

As an example of the free-free beam vibrator, WO2001/082467 discloses a beam vibrator including two pairs of beam portions extended from a vibrating portion in a line-symmetrical manner with respect to the vibrating portion.

However, stress occurs in the vibrating portion of the MEMS vibrator described above as the vibrating portion vibrates. Therefore, with the vibration frequency of the vibrating portion, bending vibration may occur in which the wave of vibration occurs in the first direction in which the beam portion is extended, and the node of vibration is formed in the second direction, giving rise to a problem that a desired vibration mode or vibration frequency cannot be obtained.

### SUMMARY

An advantage of some aspects of the invention is to solve at least a part of the problems described above, and the invention can be implemented as the following forms or application examples.

### Application Example 1

A MEMS vibrator according to this application example includes: a vibrating portion; an electrode portion provided to face the vibrating portion with a gap therebetween; and a support portion extended in a first direction from the vibrating portion, wherein the vibrating portion includes a functional portion including a concave portion or a convex portion in a cross section viewed from the first direction.

According to the MEMS vibrator with this configuration, a potential is applied between the vibrating portion and the electrode portion provided to face the vibrating portion with a gap therebetween, so that the vibrating portion is electrostatically attracted to the electrode portion. Therefore, by repeating the application and release of the potential, the vibrating portion can vibrate.

Since the vibrating portion includes the functional portion including the concave portion or the convex portion in the cross section viewed from the first direction, stress is likely to occur in the second direction intersecting the first direction, compared to the first direction, when flexure occurs in the vibrating portion.

Therefore, when flexure occurs in the vibrating portion, the vibrating portion can easily flex in a direction parallel to the first direction with the support portion as a support axis.

Hence, it is possible to obtain the MEMS vibrator with which, when the vibrating portion performs bending vibration, the following vibration mode is obtained: the node of vibration is positioned in the first direction in which the support portion is extended, the wave of vibration propagates in the second direction intersecting the first direction, and the antinode of vibration is formed in the third direction orthogonal to the first direction and the second direction.

### Application Example 2

A MEMS vibrator according to this application example includes: a vibrating portion; an electrode portion provided to face the vibrating portion with a gap therebetween; and a support portion extended in a first direction from the vibrating portion, wherein the vibrating portion includes a functional portion having a different thickness viewed from the first direction.

According to the MEMS vibrator with this configuration, a potential is applied between the vibrating portion and the electrode portion provided to face the vibrating portion with a gap therebetween, so that the vibrating portion is electrostatically attracted to the electrode portion. Therefore, by repeating the application and release of the potential, the vibrating portion can vibrate.

Since the vibrating portion includes the functional portion having a different thickness viewed from the first direction, stress is likely to occur in the second direction intersecting the first direction, compared to the first direction, when flexure occurs in the vibrating portion.

Therefore, when flexure occurs in the vibrating portion, the vibrating portion can easily flex in a direction parallel to the first direction with the support portions as a support axis.

Hence, it is possible to obtain the MEMS vibrator with which, when the vibrating portion performs bending vibration, the following vibration mode is obtained: the node of vibration is positioned in the first direction in which the support portion is extended, the wave of vibration propagates in the second direction intersecting the first direction, and the antinode of vibration is formed in the third direction orthogonal to the first direction and the second direction.

### Application Example 3

In the MEMS vibrator according to the application example described above, it is preferable that a plurality of the functional portions are arranged in parallel along a second direction intersecting the first direction.

According to the MEMS vibrator with this configuration, the functional portions are provided in parallel along the first direction in which the support portion is extended. Therefore, in the vibrating portion, compared to the MEMS vibrator described above, stress for the flexure is likely to occur in the second direction intersecting the first direction, compared to the first direction, when flexure occurs.

Therefore, when flexure occurs in the vibrating portion, the vibrating portion can further easily flex in the direction parallel to the first direction with the support portion as a support axis.

Hence, it is possible to obtain the MEMS vibrator with which, when the vibrating portion performs bending vibration, the following vibration mode is obtained: the node of vibration is positioned in the first direction in which the support portion is extended, the wave of vibration propagates in the second direction intersecting the first direction, and the antinode of vibration is formed in the third direction orthogonal to the first direction and the second direction.

### Application Example 4

In the MEMS vibrator according to the application example described above, it is preferable that the functional portion is provided with a convex portion on one surface of the vibrating portion facing the electrode portion, and provided with a concave portion opposing the convex portion in the other surface of the vibrating portion opposing the one surface.

According to the MEMS vibrator with this configuration, the functional portion is configured to include the convex portion provided on the one surface of the vibrating portion facing the electrode portion and the concave portion provided so as to oppose the convex portion in the other surface of the vibrating portion opposing the one surface, and extended in the first direction.

Therefore, when flexure occurs, stress for the flexure is likely to occur in the second direction intersecting the first direction, compared to the first direction, much more in the vibrating portion than in the MEMS vibrator described above. Moreover, the torsion of the vibrating portion occurring in the second direction can be suppressed by the convex portion and the concave portion.

Hence, it is possible to obtain the MEMS vibrator with which, when the vibrating portion performs bending vibration, the following vibration mode is obtained: the node of vibration is positioned in the first direction in which the support portion is extended, the wave of vibration propagates in the second direction intersecting the first direction, and the antinode of vibration is formed in the third direction orthogonal to the first direction and the second direction.

### Application Example 5

In the MEMS vibrator according to the application example described above, it is preferable that the functional portion is provided with a concave portion in one surface of the vibrating portion facing the electrode portion, and provided with a convex portion opposing the concave portion on the other surface of the vibrating portion opposing the one surface.

According to the MEMS vibrator with this configuration, the functional portion is configured to include the concave portion provided in the one surface of the vibrating portion facing the electrode portion and the convex portion provided so as to oppose the concave portion on the other surface of the vibrating portion opposing the one surface, and extended in the first direction.

Therefore, when flexure occurs, stress for the flexure is likely to occur in the second direction intersecting the first direction, compared to the first direction, more in the vibrating portion than in the MEMS vibrator described above. Moreover, the torsion of the vibrating portion occurring in the second direction can be suppressed by the concave portion and the convex portion.

Hence, it is possible to obtain the MEMS vibrator with which, when the vibrating portion performs bending vibration, the following vibration mode is obtained: the node of vibration is positioned in the first direction in which the support portion is extended, the wave of vibration propagates in the second direction intersecting the first direction, and the antinode of vibration is formed in the third direction orthogonal to the first direction and the second direction.

### Application Example 6

In the MEMS vibrator according to the application example described above, it is preferable that the functional portion is provided with a first convex portion on one surface of the vibrating portion facing the electrode portion, and provided with a second convex portion opposing the first convex portion on the other surface of the vibrating portion opposing the one surface.

According to the MEMS vibrator with this configuration, the functional portion is configured to include the first convex portion provided on the one surface of the vibrating portion facing the electrode portion and the second convex portion provided so as to oppose the first convex portion on the other surface of the vibrating portion opposing the one surface, and extended in the first direction.

Therefore, when flexure occurs, stress for the flexure is likely to occur in the second direction intersecting the first direction, compared to the first direction, more in the vibrating portion than in the MEMS vibrator described above. Moreover, the torsion of the vibrating portion occurring in the second direction can be suppressed by the first convex portion and the second convex portion.

Hence, it is possible to obtain the MEMS vibrator with which, when the vibrating portion performs bending vibration, the following vibration mode is obtained: the node of vibration is positioned in the first direction in which the support portion is extended, the wave of vibration propagates in the second direction intersecting the first direction, and the antinode of vibration is formed in the third direction orthogonal to the first direction and the second direction.

### Application Example 7

In the MEMS vibrator according to the application example described above, it is preferable that the functional portion is provided with a first concave portion in one surface of the vibrating portion facing the electrode portion, and provided with a second concave portion opposing the first concave portion in the other surface of the vibrating portion opposing the one surface.

According to the MEMS vibrator with this configuration, the functional portion is configured to include the first concave portion provided on the one surface of the vibrating portion facing the electrode portion and the second concave portion provided so as to oppose the first concave portion on the other surface of the vibrating portion different from the one surface, and extended in the first direction.

Therefore, when flexure occurs, stress for the flexure is likely to occur in the second direction intersecting the first direction, compared to the first direction, more in the vibrating portion than in the MEMS vibrator described above. Moreover, the torsion of the vibrating portion occurring in the second direction can be suppressed by the first concave portion and the second concave portion.

Hence, it is possible to obtain the MEMS vibrator with which, when the vibrating portion performs bending vibration, the following vibration mode is obtained: the node of vibration is positioned in the first direction in which the support portion is extended, the wave of vibration propagates in the second direction intersecting the first direction, and the antinode of vibration is formed in the third direction orthogonal to the first direction and the second direction.

### Application Example 8

In the MEMS vibrator according to the application example described above, it is preferable that the functional portion is extended in the first direction from one outer edge of the vibrating portion toward the other outer edge as an opposite side, the outer edges extending in the second direction intersecting the first direction.

According to the MEMS vibrator with this configuration, the functional portion is extended in the first direction from the one outer edge of the vibrating portion toward the other outer edge as an opposite side, the outer edges extending in the second direction. Therefore, when flexure occurs in the vibrating portion, stress for the flexure is likely to occur in the second direction intersecting the first direction, compared to the first direction.

Therefore, when flexure occurs in the vibrating portion, the vibrating portion can easily flex in a direction parallel to the first direction with the support portions as a support axis.

Hence, it is possible to obtain the MEMS vibrator with which, when the vibrating portion vibrates, the following vibration mode is obtained: the node of vibration is positioned in the first direction in which the support portion is extended, the wave of vibration propagates in the second direction intersecting the first direction, and the antinode of vibration is formed in the third direction orthogonal to the first direction and the second direction.

### Application Example 9

A MEMS vibrator according to this application example includes: a vibrating portion; an electrode portion provided to face the vibrating portion with a gap therebetween; and a support portion extended in a first direction from the vibrating portion, wherein the vibrating portion is provided with a functional portion on both end surfaces in a second direction intersecting the first direction, the functional portion including a groove portion extending in the first direction.

According to the MEMS vibrator with this configuration, a potential is applied between the vibrating portion and the electrode portion provided to face the vibrating portion with a gap therebetween, so that the vibrating portion is electrostatically attracted to the electrode portion. Therefore, by repeating the application and release of the potential, the vibrating portion can vibrate.

The vibrating portion is provided with the functional portion on the both end surfaces in the second direction intersecting the first direction, and the functional portion includes the groove portion extending in the first direction. Therefore, when flexure occurs in the vibrating portion, stress for the flexure is likely to occur in the second direction intersecting the first direction, compared to the first direction.

Therefore, when flexure occurs in the vibrating portion, the vibrating portion can easily flex in the direction parallel to the first direction with the support portions as a support axis.

Hence, it is possible to obtain the MEMS vibrator with which, when the vibrating portion performs bending vibration, the following vibration mode is obtained: the node of vibration is positioned in the first direction in which the support portion is extended, the wave of vibration propagates in the second direction intersecting the first direction, and the antinode of vibration is formed in the third direction orthogonal to the first direction and the second direction.

### Application Example 10

An electronic apparatus according to this application example includes any of the MEMS vibrators described above.

According to the electronic apparatus with this configuration, any of the MEMS vibrators with which desired vibration mode and vibration frequency are obtained is mounted in the electronic apparatus, so that the reliability of the electronic apparatus can be enhanced.

### Application Example 11

A moving object according to this application example includes any of the MEMS vibrators described above.

According to the moving object with this configuration, any of the MEMS vibrators with which desired vibration mode and vibration frequency are obtained is mounted in the moving object, so that the reliability of the moving object can be enhanced.

### BRIEF DESCRIPTION OF THE DRAWINGS

The invention will be described with reference to the accompanying drawings, wherein like numbers reference like elements.

FIG. 1 is a plan view schematically showing a MEMS vibrator according to a first embodiment.

FIGS. 2A and 2B are cross-sectional views schematically showing the MEMS vibrator according to the first embodiment.

FIG. 3 explains the operation of the MEMS vibrator according to the first embodiment.

FIGS. 4A to 4D explain manufacturing steps of the MEMS vibrator according to the first embodiment.

FIGS. 5E to 5H explain manufacturing steps of the MEMS vibrator according to the first embodiment.

FIGS. 6I and 6J explain manufacturing steps of the MEMS vibrator according to the first embodiment.

FIG. 7 is a plan view schematically showing a MEMS vibrator according to a second embodiment.

FIGS. 8A and 8B are cross-sectional views schematically showing the MEMS vibrator according to the second embodiment.

FIGS. 9A to 9C are cross-sectional views schematically showing MEMS vibrators according to modified examples.

FIGS. 10D to 10G are cross-sectional views schematically showing MEMS vibrators according to modified examples.

FIG. 11 schematically shows a personal computer as an electronic apparatus according to an embodiment.

FIG. 12 schematically shows a mobile phone as an electronic apparatus according to an embodiment.

FIG. 13 schematically shows a digital still camera as an electronic apparatus according to an embodiment.

FIG. 14 schematically shows an automobile as a moving object according to an embodiment.

### DESCRIPTION OF EXEMPLARY EMBODIMENTS

Hereinafter, a first embodiment of the invention will be described with reference to the drawings. In the drawings shown below, dimensions and ratios of components are shown appropriately different from actual ones in some cases to show the components in sizes recognizable on the drawings.

### First Embodiment

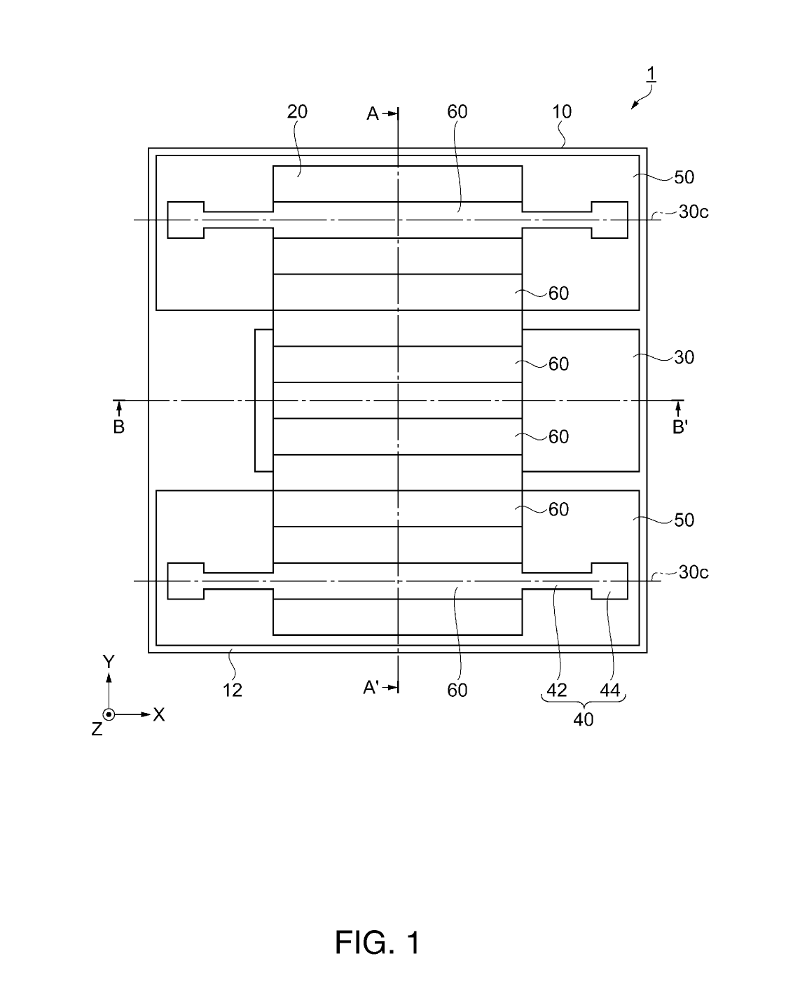

A MEMS vibrator according to the first embodiment will be described with reference to FIGS. 1 to 6J.

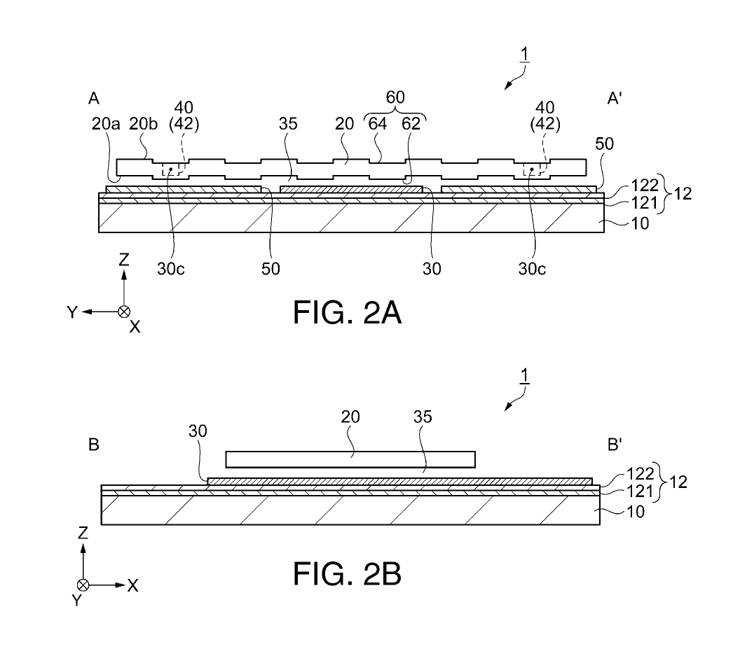

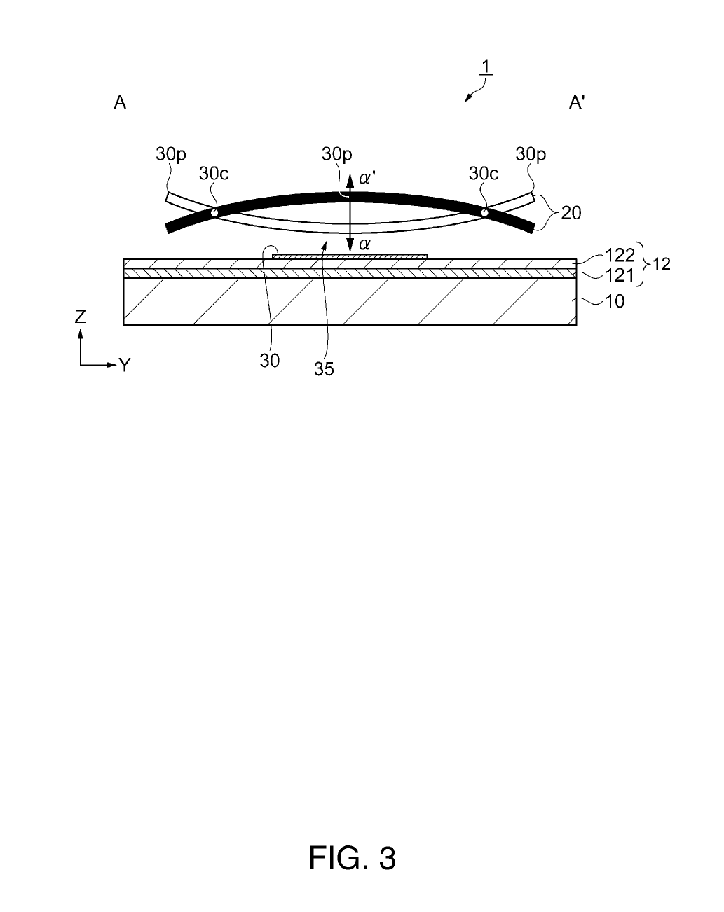

FIG. 1 is a schematic plan view schematically showing the MEMS vibrator according to the first embodiment. FIGS. 2A and 2B are cross-sectional views schematically showing cross sections of the MEMS vibrator along the line A-A′ and the line B-B′ in FIG. 1. FIG. 3 explains the operation of the MEMS vibrator.

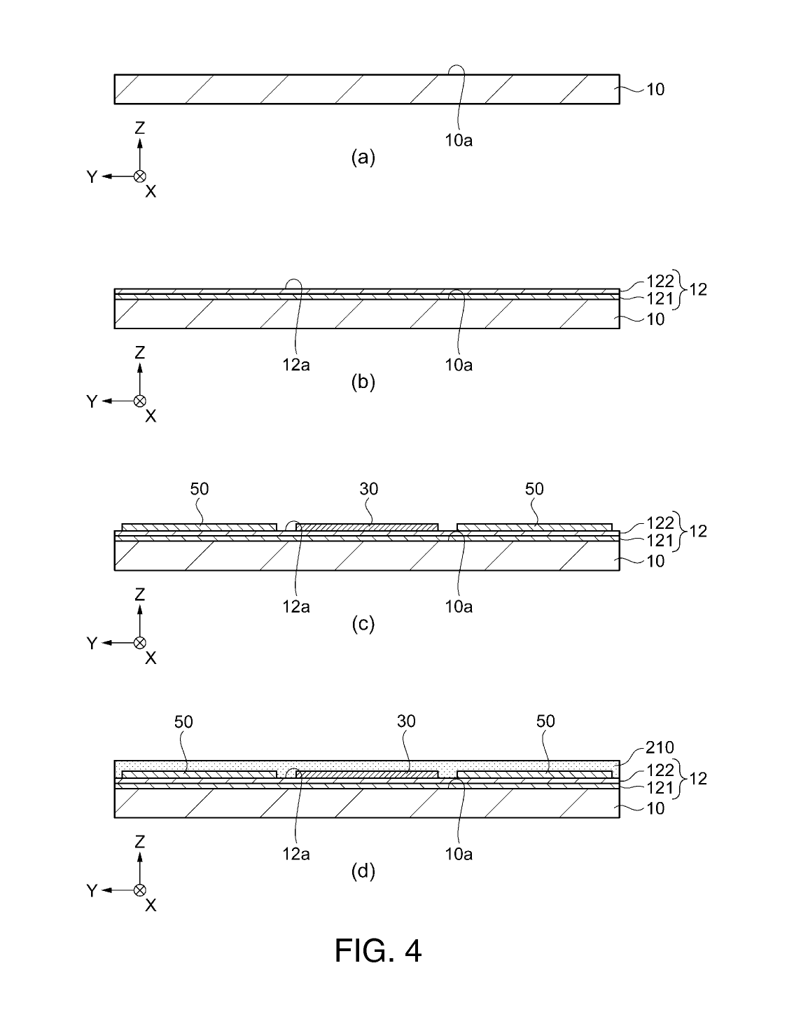

FIGS. 4A to 6J schematically show cross sections of the MEMS vibrator along the line A-A′ in FIG. 1, explaining manufacturing steps of the MEMS vibrator.

In FIGS. 1 to 6J, the X-axis, the Y-axis, and the Z-axis are shown as three axes orthogonal to each other. The Z-axis is an axis indicating a thickness direction in which an insulating portion and the like are stacked on a substrate.

### Structure of MEMS Vibrator 1

The MEMS vibrator 1 according to the first embodiment is a so-called free-free beam MEMS vibrator. In the MEMS vibrator 1, as shown in FIGS. 1 to 2B, a vibrating portion 20, support portions 40 extended from the vibrating portion 20, and fixing portions 50 fixing the support portions 40 to a substrate 10 are provided above the substrate 10. Moreover, a fixed electrode 30 for vibrating the vibrating portion 20 is provided above the substrate 10. The support portion 40 is configured to include a beam portion 42 and a post portion 44. In the vibrating portion 20, functional portions 60 are extended in a first direction in which nodes of vibration 30c at which the support portion 40 are connected extend.

### Substrate 10

The substrate 10 is a base material provided with the vibrating portion 20 and the like. For the substrate 10, a silicon substrate that is easily processed by a semiconductor fabrication technique is preferably used. The substrate 10 is not limited to a silicon substrate, and, for example, a glass substrate can be used.

In the subsequent description, the configuration of the MEMS vibrator 1 will be described while one surface of the substrate 10 provided with the vibrating portion 20 and the like is referred to as a main surface 10a.

### Insulating Portion 12

The insulating portion 12 is provided to be stacked on the main surface 10a of the substrate 10.

The insulating portion 12 is provided for electrical insulation between the substrate 10, and the fixed electrode 30 and the fixing portion 50 described later.

The insulating portion 12 is configured to include a first insulating portion 121 and a second insulating portion 122.

The first insulating portion 121 is configured to contain silicon oxide (SiO₂) as the material thereof.

The second insulating portion 122 is configured to contain silicon nitride (Si₃N₄) as the material thereof.

The material of the insulating portion 12 is not particularly limited, and may be appropriately changed as long as the material can provide the insulation between the substrate 10, and the fixed electrode 30 and the fixing portion 50, and protect the substrate 10 when forming the vibrating portion 20 and the like described later.

In the subsequent description, the configuration of the MEMS vibrator 1 will be described while one surface of the insulating portion 12 provided with the vibrating portion 20 and the like is referred to as a main surface 12a.

### Vibrating Portion 20, Fixed Electrode 30, Support Portion 40, Fixing Portion 50, and Functional Portion 60

The substrate 10 is provided with the vibrating portion 20 via the main surface 12a of the insulating portion 12, the fixed electrode 30, the support portions 40 extended from the vibrating portion 20, and the fixing portions 50.

### Vibrating Portion 20 and Functional Portion 60

The vibrating portion 20 is provided such that a portion thereof overlaps the fixed electrode 30 with a gap 35 relative to the fixed electrode 30 when planarly viewed from a direction vertical to the main surface 12a.

The vibrating portion 20 can vibrate due to electrostatic attraction acting between the vibrating portion 20 and the fixed electrode 30. When the vibrating portion 20 vibrates, the nodes of vibration 30c and antinodes of vibration 30p are formed in the vibrating portion 20. The vibration operation of the vibrating portion 20 will be described later.

The vibrating portion 20 of the MEMS vibrator 1 of the first embodiment is provided with the functional portions 60.

The functional portion 60 includes a portion having a different thickness viewed from the first direction in which the support portion 40 is extended. The functional portion 60 is configured to include a convex portion 62 provided on one surface 20a on the side facing the fixed electrode 30 and a concave portion 64 provided so as to oppose the convex portion 62 in the other surface 20b opposing the one surface 20a on the side facing the fixed electrode 30.

The convex portion 62 is provided in the vibrating portion 20 so as to protrude toward a direction in which the fixed electrode 30 is provided. The concave portion 64 is provided in the vibrating portion 20 so as to be opened toward the opposite direction from the direction in which the fixed electrode 30 is provided.

As shown in FIG. 1, in the plan view of the vibrating portion 20 from the Z-axis direction as a direction vertical to the substrate 10, the functional portion 60 is extended in the X-axis direction intersecting the Z-axis direction. That is, the functional portion 60 is extended along the X-axis direction as the first direction in which the node of vibration 30c (the imaginary line) of the vibrating portion 20 extends. Moreover, the functional portion 60 is extended in parallel with the node of vibration 30c from one outer edge of the vibrating portion 20 to the other outer edge as an opposite side.

It is sufficient that at least one functional portion is provided. By providing a plurality of functional portions 60, the vibrating portion 20 can be more easily bent in a second direction. Moreover, the convex portion 62 and the concave portion 64 may be discontinuously provided as long as the functional portion 60 is extended in the first direction. That is, it is sufficient that the functional portion 60 is extended in a row in the first direction.

The vibrating portion 20 is configured to contain polysilicon (polycrystalline silicon) as the material thereof. The material of the vibrating portion 20 is not particularly limited, and a conductive member such as amorphous silicon, gold (Au), titanium (Ti), or an alloy containing these can be used.

### Fixed Electrode 30

As shown in FIG. 1, the fixed electrode 30 is provided on the substrate 10 via the main surface 12a. The fixed electrode 30 is provided such that at least a portion thereof overlaps the vibrating portion 20 with the gap 35 therebetween in the plan view from the Z-axis direction as the direction vertical to the substrate 10 (the main surface 12a). When a potential is applied to the fixed electrode 30 together with the vibrating portion 20 as a movable electrode, charge can be generated between the fixed electrode 30 and the vibrating portion 20. The fixed electrode 30 can electrostatically attract the vibrating portion 20 with the generated charge.

The fixed electrode 30 is, for example, a rectangularly patterned electrode, and configured to contain polysilicon as the material thereof. The material of the fixed electrode 30 is not particularly limited, and, for example, a conductive member such as amorphous silicon, gold (Au), titanium (Ti), or an alloy containing these can be used.

### Support Portion 40

The support portion 40 is extended from the vibrating portion 20 toward the fixing portion 50. The support portion 40 is composed of the beam portion 42 and the post portion 44.

The support portion 40 is provided to support the vibrating portion 20 and fix the vibrating portion 20 to the substrate 10. In the support portion 40, the beam portion 42 is extended toward the post portion 44 in the first direction in which the node of vibration 30c of the vibrating portion 20 extends, and the post portion 44 is provided toward the fixing portion 50 in a third direction (the Z-axis direction) intersecting the first direction (the X-axis direction). The support portion 40 is connected at the post portion 44 to the fixing portion 50.

In the MEMS vibrator 1 of the first embodiment, the vibrating portion 20 is supported by two pairs of support portions 40 that are line-symmetrical with respect to the vibrating portion 20. However, this is not restrictive. The vibrating portion 20 may be supported by one support portion 40 as long as the support portion 40 is extended from the node of vibration 30c. Moreover, the vibrating portion 20 may be supported by two support portions 40 that are line-symmetrical or point-symmetrical with respect to the vibrating portion 20.

### Fixing Portion 50

The fixing portions 50 are provided on the substrate 10 via the insulating portion 12. To the fixing portion 50, the support portion 40 extended from the vibrating portion 20 is connected. The fixing portion 50 is provided to fix the support portion 40 to the substrate 10, and also to maintain the two (a pair of) support portions 40 that are extended from the vibrating portion 20 in a line-symmetrical manner at the same potential for stabilizing the vibration of the vibrating portion 20.

The fixing portion 50 is, for example, a rectangularly patterned electrode similarly to the fixed electrode 30, and a conductive member such as polysilicon, amorphous silicon, gold (Au), titanium (Ti), or an alloy containing these can be used as the material thereof.

### Operation of MEMS Vibrator 1

FIG. 3 is a cross-sectional view of the MEMS vibrator 1 along the line A-A′ in FIG. 1, showing the vibration operation of the vibrating portion 20 as a movable electrode.

In the MEMS vibrator 1 of the first embodiment, an excitation signal (potential) generated in a circuit portion (not shown) can be applied between the vibrating portion 20 and the fixed electrode 30. The application of the excitation signal to the vibrating portion 20 can be performed from the fixing portion 50 via the support portion 40. Moreover, an electric signal obtained as a result of vibration of the vibrating portion 20 can be extracted from the fixed electrode 30 and the fixing portion 50 via the support portion 40 extended from the vibrating portion 20.

In the MEMS vibrator 1, when a potential as an excitation signal is applied between the vibrating portion 20 and the fixed electrode 30, charge is generated between the electrodes. With the charge generated between the vibrating portion 20 and the fixed electrode 30, electrostatic attraction with respect to the fixed electrode 30 acts on the vibrating portion 20, so that the vibrating portion 20 is attracted in a direction α of the fixed electrode 30. Moreover, when the application of voltage is released, the vibrating portion 20 is separated from the fixed electrode 30 in an opposite direction α′. The vibrating portion 20 can perform bending vibration by repeating the attraction and separation described above.

The vibration of the vibrating portion 20 is flexural vibration in which the antinodes of vibration (vibration amplitude) 30p are positioned at the center portion where the vibrating portion 20 and the fixed electrode 30 overlap each other and at both end portions of the vibrating portion 20, and each of the nodes of vibration (vibration amplitude) 30c is positioned between the antinodes of vibration (vibration amplitude) 30p. The node of vibration 30c is an inflection point of vibration (vibration amplitude).

The vibration of the vibrating portion 20 is bending vibration (motion) with the node of vibration 30c as a support axis.

For enabling the bending vibration described above, the support portion 40 (the beam portion 42) is connected to the portion at which the node of vibration 30c is positioned, to support the vibrating portion 20.

### Method for Manufacturing MEMS Vibrator 1

Next, a method for manufacturing the MEMS vibrator 1 will be described.

FIGS. 4A to 6J are cross-sectional views explaining, in the order of steps, the method for manufacturing the MEMS vibrator 1 according to the first embodiment. FIGS. 4A to 6J schematically show cross sections of the MEMS vibrator 1 along the line A-A′ in FIG. 1.

The steps of manufacturing the MEMS vibrator 1 of the first embodiment include a step of preparing the substrate 10 including the main surface 10a on which the insulating portion 12, the vibrating portion 20, the fixed electrode 30, and the like are formed. Moreover, the steps of manufacturing the MEMS vibrator 1 include a step of forming the insulating portion 12 on the substrate 10, and a step of forming the fixed electrode 30 and the fixing portion 50 on the insulating portion 12. Further, the steps of manufacturing the MEMS vibrator 1 include a step of forming the vibrating portion 20 with the gap 35 relative to the fixed electrode 30.

### Preparing Step of Substrate 10

FIG. 4A shows a state where the substrate 10 for forming the MEMS vibrator 1 is prepared.

The step of preparing the substrate 10 is a step of preparing the substrate 10 on which the insulating portion 12, the vibrating portion 20, the fixed electrode 30, and the like are formed in the steps described later. For the substrate 10, for example, a silicon substrate can be used. Also in the description of the method for manufacturing the MEMS vibrator 1, the steps will be described while one surface of the substrate 10 on which the insulating portion 12, the vibrating portion 20, the fixed electrode 30, and the like are formed is referred to as the main surface 10a.

### Forming Step of Insulating Portion 12

FIG. 4B shows a state where the insulating portion 12 is formed on the main surface 10a of the substrate 10.

The step of forming the insulating portion 12 is a step of forming the insulating portion 12 on the main surface 10a of the substrate 10 prepared in the step described above.

The insulating portion 12 of the MEMS vibrator 1 of the first embodiment is composed of the first insulating portion 121 and the second insulating portion 122 in this order from the main surface 10a side of the substrate 10. Also in the description of the method for manufacturing the MEMS vibrator 1, the steps will be described while one surface of the insulating portion 12 on the side where the second insulating portion 122 is formed is referred to as the main surface 12a.

In a step of forming the first insulating portion 121, for example, a silicon oxide (SiO₂) film can be formed as the first insulating portion 121 by a chemical vapor deposition (CVD) method. The step of forming the first insulating portion 121 is not limited to a CVD method, and the silicon oxide film may be formed by thermally oxidizing the main surface 10a of the silicon substrate as the substrate 10 by a thermal oxidation method. The first insulating portion 121 is formed substantially on the entire surface of the substrate 10 in correspondence with the main surface 10a.

In a step of forming the second insulating portion 122, for example, a silicon nitride (Si₃N₄) film as the second insulating portion 122 can be formed by a CVD method. The step of forming the second insulating portion 122 is not limited to a CVD method, and the silicon nitride film may be formed by heating the silicon substrate as the substrate 10 in an atmosphere of nitrogen gas and hydrogen gas.

The second insulating portion 122 is formed substantially on the entire surface of the first insulating portion 121 in correspondence therewith.

### Forming Step of Fixed Electrode 30 and Fixing Portion 50

FIG. 4C shows a state where the fixed electrode 30 and the fixing portions 50 are formed on the main surface 12a of the insulating portion 12.

The step of forming the fixed electrode 30 is a step of forming the fixed electrode 30 on the main surface 12a side of the insulating portion 12 described above, that is, on the second insulating portion 122.

In the step of forming the fixed electrode 30, for example, the fixed electrode 30 containing a conductive material such as polysilicon, amorphous silicon, gold (Au), or titanium (Ti) can be formed by a CVD method. In addition to the fixed electrode 30, the fixing portion 50 is formed on the second insulating portion 122 in the step described later. Therefore, a mask is applied to a region on the second insulating portion 122 where the formation of the fixed electrode 30 is not desired, and then the fixed electrode 30 is formed.

The method for forming the fixed electrode 30 is not limited to a CVD method, and the fixed electrode 30 containing various kinds of conductive materials may be formed using a physical vapor deposition (PVD) method or the like.

The step of forming the fixing portion 50 is a step of forming the fixing portion 50 on the main surface 12a side of the insulating portion 12 described above, that is, on the second insulating portion 122.

In the step of forming the fixing portion 50, for example, the fixing portion 50 containing polysilicon, amorphous silicon, gold (Au), titanium (Ti), or the like can be formed by a CVD method. In the step of forming the fixing portion 50, the fixing portion 50 having a thickness substantially equal to that of the fixed electrode 30 is preferably formed. By making the thicknesses substantially equal to each other, the thickness of a later-described sacrificial layer 210 to be formed on the fixed electrode 30, the fixing portion 50, and the like is made uniform, so that it is possible to suppress the occurrence of unnecessary unevenness of the vibrating portion 20 to be formed on the sacrificial layer 210. In addition to the fixing portion 50, the fixed electrode 30 described above is formed on the second insulating portion 122. Therefore, it is preferable that a mask is applied to a region on the second insulating portion 122 where the formation of the fixing portion 50 is not desired, and then the fixing portion 50 is formed.

The method for forming the fixing portion 50 is not limited to a CVD method, and the fixing portion 50 containing various kinds of conductive materials may be formed using a PVD method or the like.

The forming steps of the fixed electrode 30 and the fixing portion 50 described above may be performed by, for example, simultaneously forming the fixed electrode 30 and the fixing portion 50 by a CVD method or the like using the same material. By simultaneously forming the fixed electrode 30 and the fixing portion 50, the thicknesses of the fixed electrode 30 and the fixing portion 50 can be easily formed to be substantially the same as each other.

### Forming Step of Sacrificial Layer 210

FIG. 4D shows a state where the sacrificial layer 210 is provided so as to cover the fixed electrode 30 and the fixing portions 50 for providing the gap 35 between the vibrating portion 20, and the fixed electrode 30 and the fixing portions 50.

As described above, the vibrating portion 20 is provided with the gap 35 relative to the fixed electrode 30 and the fixing portions 50 in the MEMS vibrator 1. The vibrating portion 20 is formed on the sacrificial layer 210 in the step described later, and the sacrificial layer 210 is removed through a later step, so that the gap 35 can be provided between the vibrating portion 20, and the fixed electrode 30 and the fixing portions 50.

The step of forming the sacrificial layer 210 is a step of forming the sacrificial layer 210 as an intermediate layer for providing the gap 35 described above. In the step of forming the sacrificial layer 210, for example, the sacrificial layer 210 containing silicon oxide can be formed by a CVD method. The method of forming the sacrificial layer 210 is not limited to a CVD method, and the sacrificial layer 210 containing silicon oxide may be formed using a PVD method or the like. As the material constituting the sacrificial layer 210, for removing the sacrificial layer 210 while leaving the vibrating portion 20, the fixed electrode 30, the fixing portion 50, and the like in the step described later, silicon oxide as a material enabling the selective removal (etching) of the sacrificial layer 210, or a compound containing silicon oxide is preferably used. The sacrificial layer 210 is not limited to silicon oxide or a compound containing silicon oxide, and the material may be appropriately changed as long as the sacrificial layer 210 can be selectively removed.

### Forming Step of Vibrating Portion 20

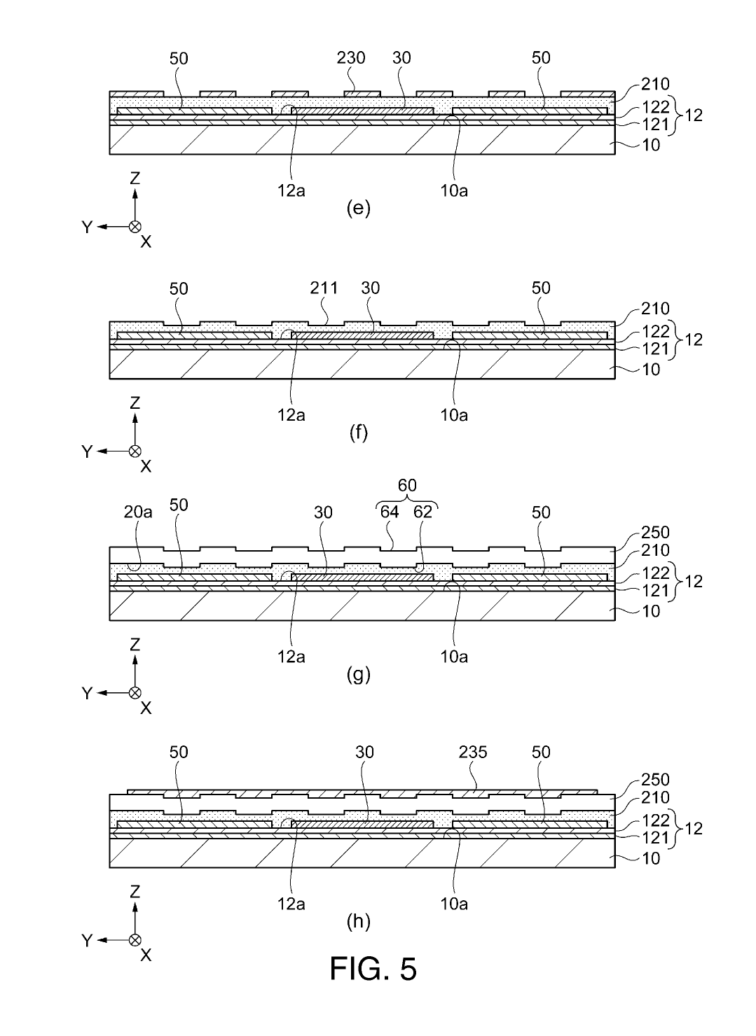

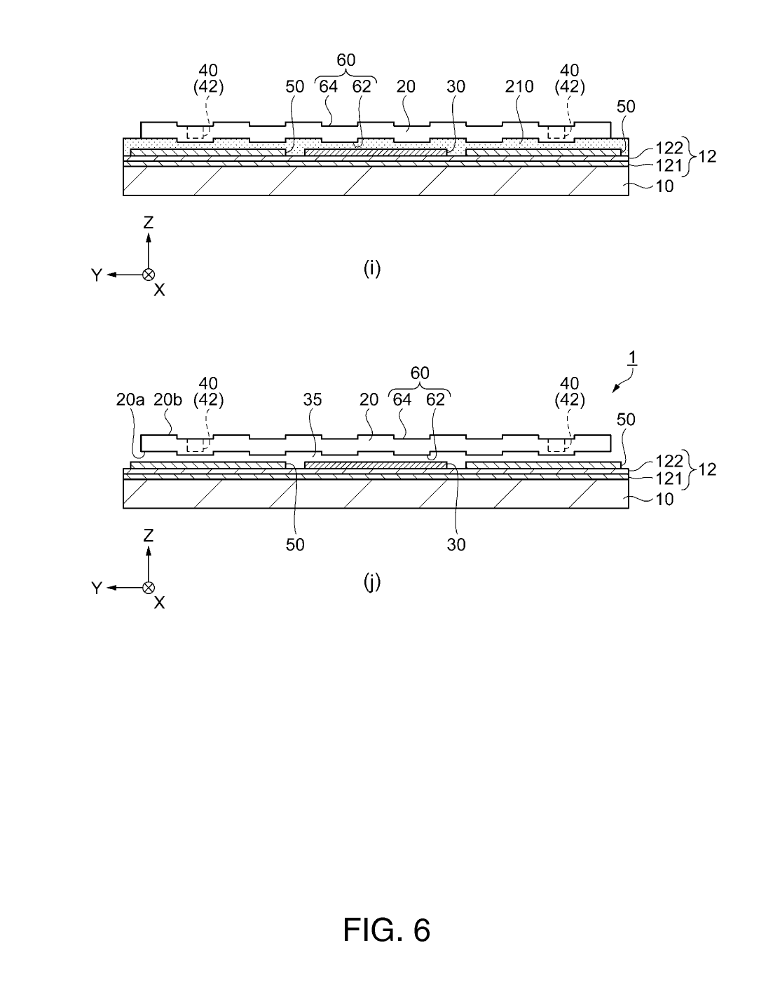

FIG. 5E shows a state where a mask pattern 230 for forming the functional portion 60 is formed on the sacrificial layer 210 formed in the prior step.

In the forming step of the vibrating portion 20, a recessed portion 211 corresponding to the convex portion 62 is first formed in the sacrificial layer 210 for forming the convex portion 62 constituting the functional portion 60 on the one surface 20a (refer to FIGS. 2A and 2B) facing the fixed electrode 30. In the formation of the recessed portion 211, the mask pattern 230 in which a portion serving as the recessed portion 211 is opened is formed on the sacrificial layer 210 using a photolithography method. Next, etching is performed on the portion where the mask pattern 230 is opened to expose the sacrificial layer 210. The etching is performed as so-called half-etching. The etching depth of the sacrificial layer 210 is set to a dimension substantially equal to the height of the convex portion 62.

FIG. 5G shows a state where a conductive layer 250 as a precursor of the vibrating portion 20 and the support portion 40 (refer to FIGS. 6I and 6J) is formed on the sacrificial layer 210.

In the step of forming the vibrating portion 20, the conductive layer 250 as a precursor of the vibrating portion 20 and the support portion 40 is next formed on the sacrificial layer 210. In the step of forming the conductive layer 250, the conductive layer 250 containing polysilicon can be formed on the sacrificial layer 210 by, for example, a CVD method.

The conductive layer 250 is formed along the recessed portion 211 formed in the sacrificial layer 210. Therefore, a convex shape (the convex portion 62) is formed along the recessed portion 211 on the conductive layer 250, while a concave shape (the concave portion 64) along the recessed portion 211 is formed in the conductive layer 250 on the opposite side.

FIG. 5H shows a state where a mask pattern 235 for patterning the vibrating portion 20 and the support portion 40 is formed on the conductive layer 250 as a precursor of the vibrating portion 20 and the support portion 40.

Next, in the step of forming the vibrating portion 20, the mask pattern 235 for removing the conductive layer 250 at an unnecessary portion for the vibrating portion 20 and the support portion 40 is formed. Next, in the step of forming the vibrating portion 20, the removal of the conductive layer 250 at a portion where the mask pattern 235 is not formed, that is, at the unnecessary portion for the vibrating portion 20 and the support portions 40 is performed. The formation of the mask pattern 235 described above and the removal of the conductive layer 250 can be performed by a photolithography method.

FIG. 6I shows a state where the unnecessary portion for the vibrating portion 20 and the support portion 40 is removed. Removing Step of Sacrificial Layer 210

FIG. 6J shows a state where the sacrificial layer 210 formed in the prior step is removed.

The step of removing the sacrificial layer 210 is a step of removing the sacrificial layer 210 formed temporarily as the intermediate layer for providing the gap 35 between the vibrating portion 20 and the fixed electrode 30.

In the step of removing the sacrificial layer 210, it is required to selectively remove the sacrificial layer 210. Therefore, in the step of removing the sacrificial layer 210, etching (removal) of the sacrificial layer 210 is performed by, for example, a wet etching method. The removal of the sacrificial layer 210 by a wet etching method is preferably performed using an etchant (cleaning fluid) containing hydrofluoric acid. With the use of the etchant containing hydrofluoric acid, the etching rate of the sacrificial layer 210 containing silicon oxide is higher than the etching rate of the vibrating portion 20, the fixed electrode 30, the support portion 40, and the fixing portion 50. Therefore, the sacrificial layer 210 can be removed selectively and efficiently.

Moreover, since the second insulating portion 122 as an under film of the fixed electrode 30 and the fixing portion 50 contains silicon nitride that is resistant to hydrofluoric acid, the second insulating portion 122 can function as a so-called etching stopper. With this configuration, it is possible in the MEMS vibrator 1 to suppress a reduction in insulation between the substrate 10, and the fixed electrode 30 and the fixing portion 50 due to the sacrificial layer 210 being etched.

In the MEMS vibrator 1, the gap 35 is generated between the vibrating portion 20 and the fixed electrode 30 by removing the sacrificial layer 210, so that the vibrating portion 20 can vibrate.

The step of removing the sacrificial layer 210 is not limited to a wet etching method, and may be performed by a dry etching method.

With the removal of the sacrificial layer 210 described above, the manufacturing steps of the MEMS vibrator 1 are completed.

According to the first embodiment described above, the following advantageous effects are obtained.

According to the MEMS vibrator 1, the functional portions 60 are provided in the vibrating portion 20 in parallel with the first direction in which the support portion 40 is extended. Therefore, in the vibrating portion 20, when flexure occurs, stress for the flexure is likely to occur in the second direction intersecting the first direction, compared to the first direction.

Therefore, when flexure occurs in the vibrating portion 20, the vibrating portion 20 can easily flex in a direction parallel to the first direction with the support portions 40 as a support axis. Moreover, the convex portion 62 and the concave portion 64 provided in the functional portion 60 act as a rib, so that the torsion of the vibrating portion 20 occurring in the second direction can be suppressed.

Hence, it is possible to obtain the MEMS vibrator 1 with which, when the vibrating portion 20 vibrates, the following vibration mode is obtained: the node of vibration 30c is positioned in the first direction in which the support portion 40 is extended, the wave of vibration propagates in the second direction intersecting the first direction, and the antinode of vibration 30p is formed in the third direction orthogonal to the first direction and the second direction.

### Second Embodiment

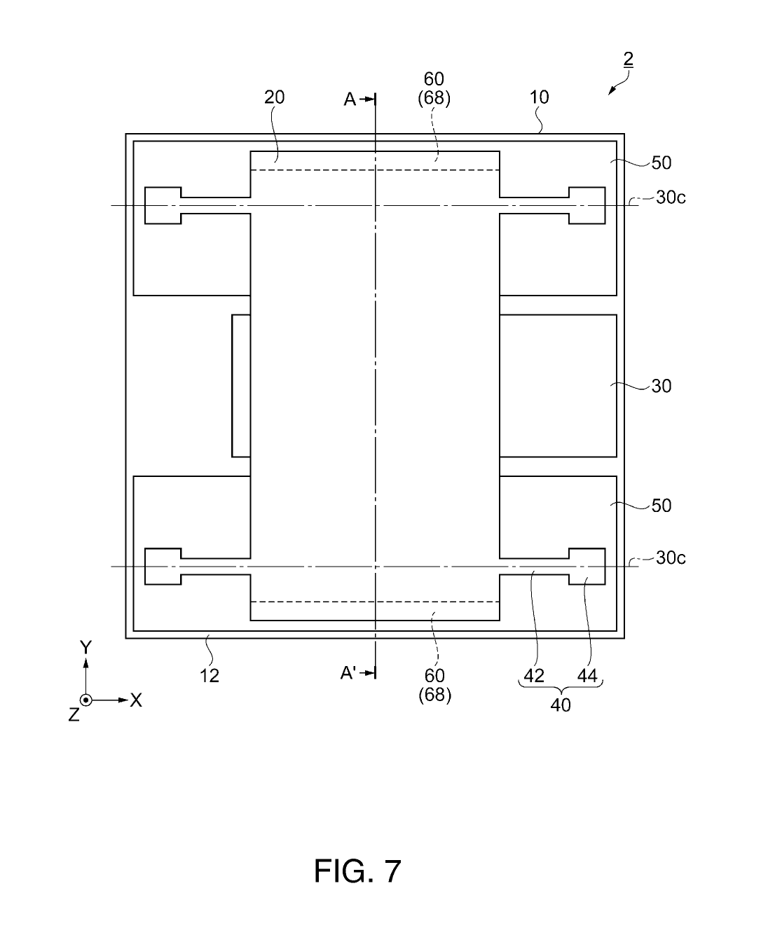

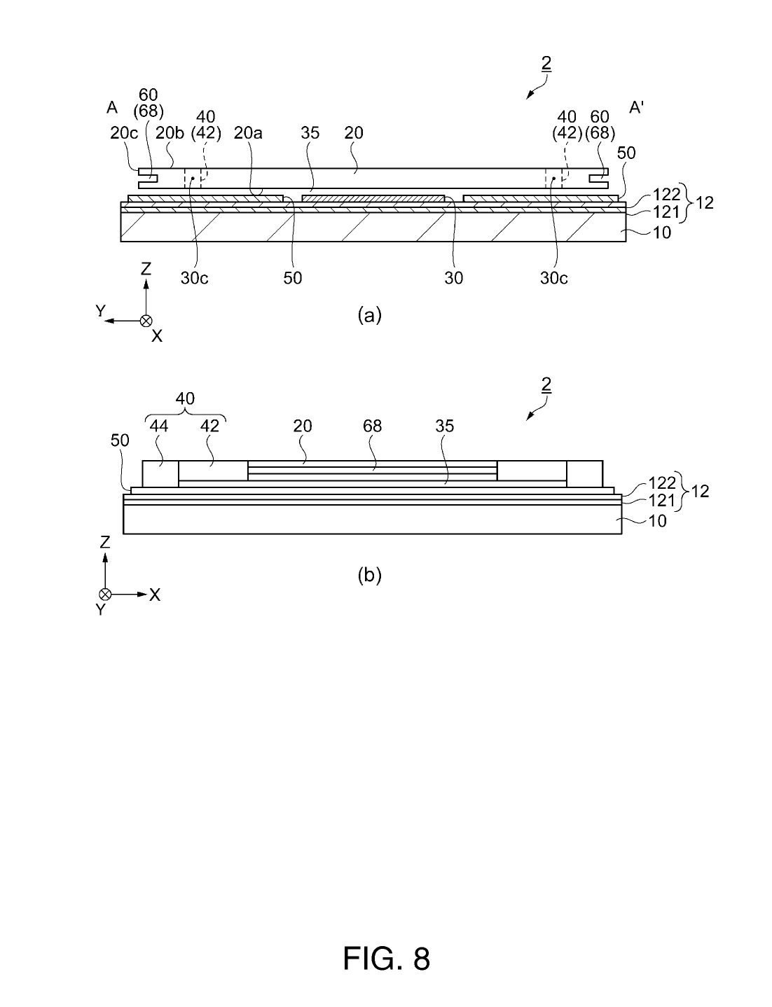

A MEMS vibrator according to a second embodiment will be described with reference to FIGS. 7 to 8B.

FIG. 7 is a schematic plan view schematically showing the MEMS vibrator according to the second embodiment. FIG. 8A is a cross-sectional view schematically showing a cross section of the MEMS vibrator along the line A-A′ in FIG. 7; and FIG. 8B is a side view schematically showing aside surface of the MEMS vibrator viewed from the Y-axis direction.

In FIGS. 7 to 8B, the X-axis, the Y-axis, and the Z-axis are shown as three axes orthogonal to each other. The Z-axis is an axis indicating the thickness direction in which the insulating portion and the like are stacked on the substrate.

The MEMS vibrator 2 according to the second embodiment differs from the MEMS vibrator 1 described in the first embodiment in the arrangement position of the functional portion 60. Since other configurations are substantially the same as those of the first embodiment, the difference is described. The same portions are denoted by the same reference and numeral signs, and the description thereof is omitted.

### Structure of MEMS Vibrator 2

The MEMS vibrator 2 according to the second embodiment is a so-called free-free beam MEMS vibrator. In the MEMS vibrator 2, as shown in FIGS. 7 to 8B, the vibrating portion 20, the support portions 40 extended from the vibrating portion 20, and the fixing portions 50 fixing the support portions 40 to the substrate 10 are provided above the substrate 10. Moreover, the fixed electrode 30 for vibrating the vibrating portion 20 is provided above the substrate 10. The support portion 40 is configured to include the beam portion 42 and the post portion 44.

In the vibrating portion 20 of the MEMS vibrator 2 according to the second embodiment, the functional portion 60 is extended, in parallel with the node of vibration 30c, at ends in the second direction intersecting the first direction in which the node of vibration 30c extends, that is, on end surfaces 20c of the vibrating portion 20 orthogonal to the first direction and the second direction.

### Functional Portion 60

As shown in FIGS. 8A and 8B, in the vibrating portion 20, the functional portion 60 is provided on the end surfaces 20c of the vibrating portion 20. The functional portion 60 is configured to include a groove portion 68. Specifically, the groove portion 68 is provided between the one surface 20a of the vibrating portion 20 on the side facing the fixed electrode and the other surface 20b opposing the one surface 20a. The groove portion 68 is extended in the first direction along the node of vibration 30c. In the MEMS vibrator 2, the side surface shape of the groove portion 68 viewed from the Z-axis direction shown in FIG. 8A is rectangular. However, the shape is not particularly limited and may be changed as long as the groove portion 68 is provided along the node of vibration 30c. Moreover, in the MEMS vibrator 2, the functional portion 60 may be provided with a hole (not shown), instead of the groove portion 68, in the first direction along the node of vibration 30c.

According to the second embodiment described above, the following advantageous effects are obtained.

According to the MEMS vibrator 2, the vibrating portion 20 is provided with the functional portion 60 on the both end surfaces 20c in the second direction intersecting the first direction, and the functional portion 60 includes the groove portion 68 extending in the first direction. With this configuration, when flexure occurs in the vibrating portion 20, stress is likely to occur in the second direction intersecting the first direction, compared to the first direction.

Therefore, when flexure occurs in the vibrating portion 20, the vibrating portion 20 can easily flex in the direction parallel to the first direction with the support portion 40 as a support axis.

Hence, it is possible to obtain the MEMS vibrator 2 with which, when the vibrating portion 20 performs bending vibration, the following vibration mode is obtained: the node of vibration 30c is positioned in the first direction in which the support portion 40 is extended, the wave of vibration propagates in the second direction intersecting the first direction, and the antinode of vibration 30p is formed in the third direction orthogonal to the first direction and the second direction.

The invention is not limited to the first embodiment described above, and various modifications or improvements can be added to the first embodiment described above. Modified examples will be described below.

### Modified Examples

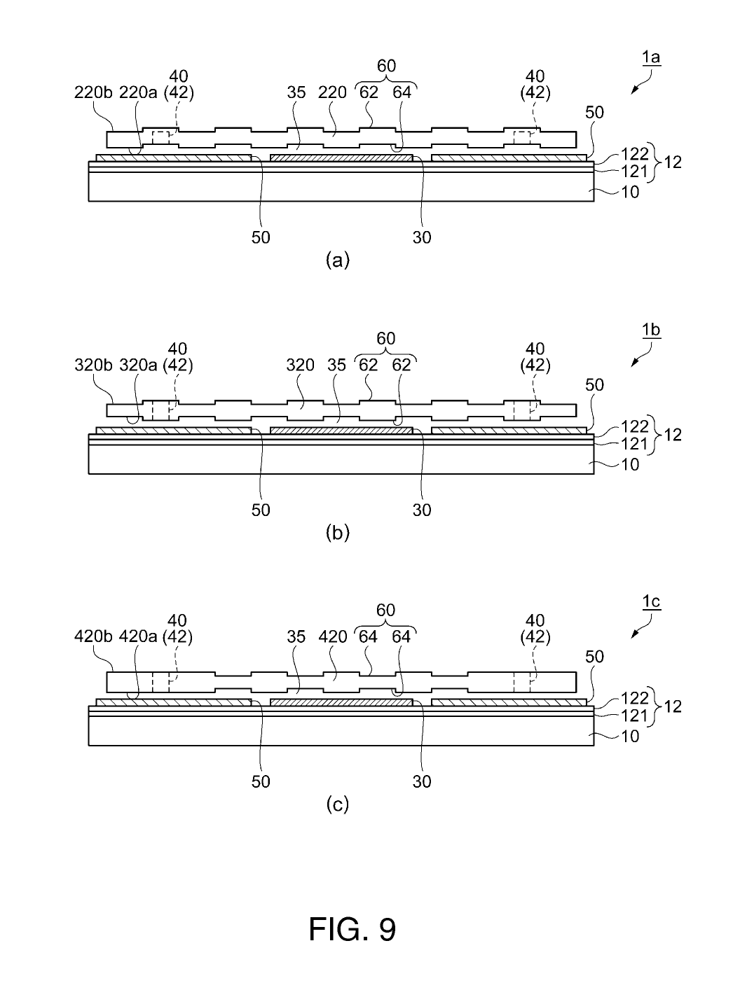

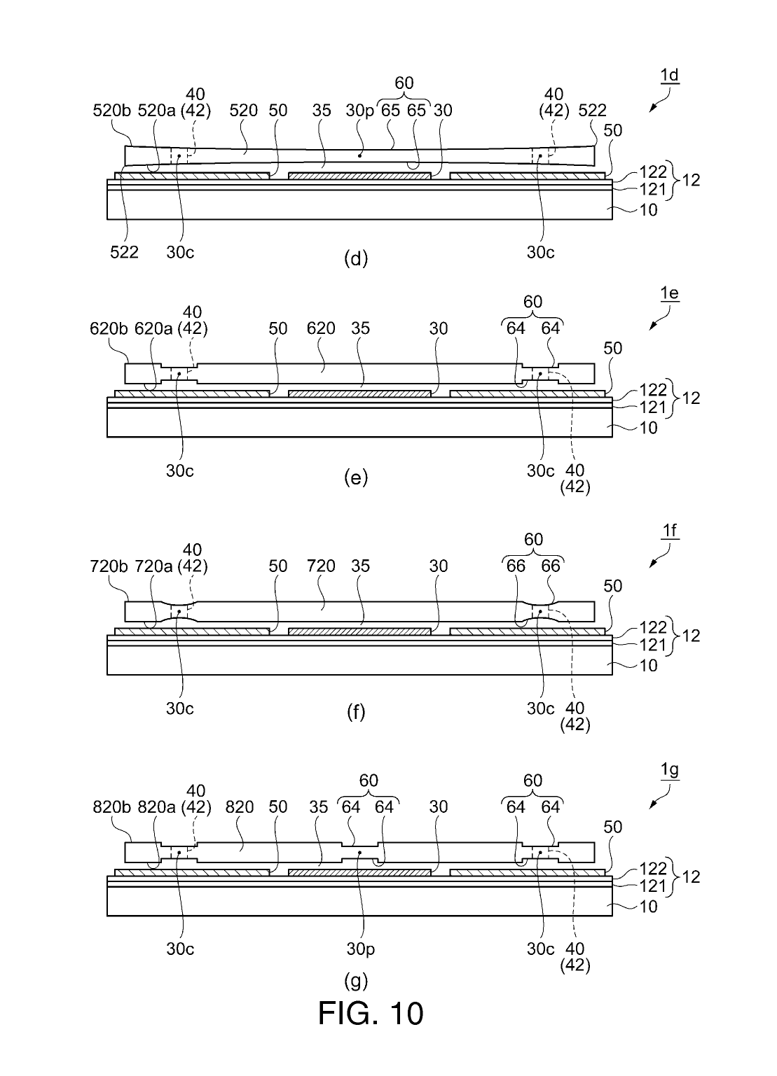

FIGS. 9A to 10G are cross-sectional views schematically showing MEMS vibrators according to the modified examples, showing the portion corresponding to the cross section of the MEMS vibrator 1 along the line A-A′ shown in FIG. 1.

The MEMS vibrators according to the modified examples are different in the shape and arrangement of the functional portion provided in the vibrating portion. The differences are described below, and the description of the same configurations and manufacturing steps is partially omitted.

### Modified Example 1

FIG. 9A is a cross-sectional view schematically showing a cross section of a vibrating portion of a MEMS vibrator according to Modified Example 1.

In the MEMS vibrator 1a according to Modified Example 1, the configuration of the functional portion 60 as a portion having a different thickness in the vibrating portion 220 differs from the vibrating portion 20 of the MEMS vibrator 1 described in the first embodiment.

As shown in FIG. 9A, the functional portion 60 provided in the vibrating portion 220 of the MEMS vibrator 1a is configured to include the concave portion 64 provided on one surface 220a of the vibrating portion 220 facing the fixed electrode 30 and the convex portion 62 provided so as to oppose the concave portion 64 on the other surface 220b opposing the one surface 220a on the side facing the fixed electrode 30. The concave portion 64 is provided in the vibrating portion 220 so as to be opened toward a direction in which the fixed electrode 30 is provided. The convex portion 62 is provided in the vibrating portion 220 so as to protrude toward the opposite direction from the direction in which the fixed electrode 30 is provided.

With this configuration, when flexure occurs in the vibrating portion 220, stress for the flexure is likely to occur in the second direction intersecting the first direction, compared to the first direction. Moreover, the concave portion 64 and the convex portion 62 act as a rib, so that the torsion of the vibrating portion 220 occurring in the second direction can be suppressed.

Hence, it is possible to obtain the MEMS vibrator 1a with which, when the vibrating portion 220 vibrates, the following vibration mode is obtained: the node of vibration 30c is positioned in the first direction in which the support portion 40 is extended, the wave of vibration propagates in the second direction intersecting the first direction, and the antinode of vibration 30p is formed in the third direction orthogonal to the first direction and the second direction.

### Modified Example 2

FIG. 9B is a cross-sectional view schematically showing a cross section of a vibrating portion of a MEMS vibrator according to Modified Example 2.

In the MEMS vibrator 1b according to Modified Example 2, the configuration of the functional portion 60 as a portion having a different thickness in the vibrating portion 320 differs from the vibrating portion 20 of the MEMS vibrator 1 described in the first embodiment.

As shown in FIG. 9B, the functional portion 60 provided in the vibrating portion 320 of the MEMS vibrator 1b is configured to include a pair of convex portions 62 provided, so as to oppose each other, on one surface 320a of the vibrating portion 320 facing the fixed electrode 30 and on the other surface 320b opposing the one surface 320a on the side facing the fixed electrode 30. The convex portion 62 as a first convex portion provided on the one surface 320a of the vibrating portion 320 is arranged so as to protrude toward the direction in which the fixed electrode 30 is provided. The convex portion 62 as a second convex portion provided on the other surface 320b of the vibrating portion 320 is arranged so as to protrude toward the opposite direction from the direction in which the fixed electrode 30 is provided.

In the MEMS vibrator 1b, when flexure occurs in the vibrating portion 320, stress for the flexure is likely to occur in the second direction intersecting the first direction, compared to the first direction. Moreover, the torsion of the vibrating portion 320 occurring in the second direction can be suppressed by the convex portions 62 provided as a pair.

Hence, it is possible to obtain the MEMS vibrator 1b with which, when the vibrating portion 320 vibrates, the following vibration mode is obtained: the node of vibration 30c is positioned in the first direction in which the support portion 40 is extended, the wave of vibration propagates in the second direction intersecting the first direction, and the antinode of vibration 30p is formed in the third direction orthogonal to the first direction and the second direction.

### Modified Example 3

FIG. 9C is a cross-sectional view schematically showing a cross section of a vibrating portion of a MEMS vibrator according to Modified Example 3.

In the MEMS vibrator 1c according to Modified Example 3, the configuration of the functional portion 60 as a portion having a different thickness in the vibrating portion 420 differs from the vibrating portion 20 of the MEMS vibrator 1 described in the first embodiment.

As shown in FIG. 9C, the functional portion 60 provided in the vibrating portion 420 of the MEMS vibrator 1c is configured to include a pair of concave portions 64 provided, so as to oppose each other, in one surface 420a of the vibrating portion 420 facing the fixed electrode 30 and in the other surface 420b opposing the one surface 420a on the side facing the fixed electrode 30. The concave portion 64 as a first concave portion provided in the one surface 420a of the vibrating portion 420 is arranged so as to be opened toward the direction in which the fixed electrode 30 is provided. The concave portion 64 as a second concave portion provided in the other surface 420b of the vibrating portion 420 is arranged so as to be opened toward the opposite direction from the direction in which the fixed electrode 30 is provided.

In the MEMS vibrator 1c, when flexure occurs in the vibrating portion 420, stress for the flexure is likely to occur in the second direction intersecting the first direction, compared to the first direction. Moreover, the torsion of the vibrating portion 420 occurring in the second direction can be suppressed by the concave portions 64 provided as a pair.

Hence, it is possible to obtain the MEMS vibrator 1c with which, when the vibrating portion 420 vibrates, the following vibration mode is obtained: the node of vibration 30c is positioned in the first direction in which the support portion 40 is extended, the wave of vibration propagates in the second direction intersecting the first direction, and the antinode of vibration 30p is formed in the third direction orthogonal to the first direction and the second direction.

### Modified Example 4

FIG. 10D is a cross-sectional view schematically showing a cross section of a vibrating portion of a MEMS vibrator according to Modified Example 4.

In the MEMS vibrator 1d according to Modified Example 4, the configuration of the functional portion 60 as a portion having a different thickness in the vibrating portion 520 differs from the vibrating portion 20 of the MEMS vibrator 1 described in the first embodiment.

As shown in FIG. 10D, the functional portion 60 of the vibrating portion 520 of the MEMS vibrator 1d is provided such that the thickness of the vibrating portion 520 varies from the node of vibration 30c toward the antinode of vibration 30p.

More specifically, the functional portion 60 is provided such that the thickness of the vibrating portion 520 viewed from the first direction in which the support portion 40 is extended is smaller at the antinode of vibration 30p provided between the nodes of vibration 30c than at the nodes of vibration 30c where the support portions 40 are extended and at ends 522 in the second direction. In the functional portion 60, a concave portion 65 provided in one surface 520a of the vibrating portion 520 facing the fixed electrode 30 includes a spherical surface forming an arc with the antinode of vibration 30p as a central point. A concave portion 65 provided in the other surface 520b of the vibrating portion 520 on the opposite side from the one surface 520a facing the fixed electrode 30 includes a spherical surface forming an arc with the antinode of vibration 30p as a central point.

In the MEMS vibrator 1d, when flexure occurs in the vibrating portion 520, the vibrating portion 520 can easily flex in the second direction with the support portion 40 as a support axis.

Hence, it is possible to obtain the MEMS vibrator 1d with which, when the vibrating portion 520 vibrates, the following vibration mode is obtained: the node of vibration 30c is positioned in the first direction in which the support portion 40 is extended, the wave of vibration propagates in the second direction intersecting the first direction, and the antinode of vibration 30p is formed in the third direction orthogonal to the first direction and the second direction.

### Modified Example 5

FIG. 10E is a cross-sectional view schematically showing a cross section of a vibrating portion of a MEMS vibrator according to Modified Example 5.

In the MEMS vibrator 1e according to Modified Example 5, the configuration of the functional portion 60 as a portion having a different thickness in the vibrating portion 620 differs from the vibrating portion 20 of the MEMS vibrator 1 described in the first embodiment.

As shown in FIG. 10E, the functional portion 60 of the vibrating portion 620 of the MEMS vibrator 1e is provided along the node of vibration 30c where the support portion 40 extends.

The functional portion 60 is configured to include a pair of concave portions 64 provided, so as to oppose each other, in one surface 620a of the vibrating portion 620 facing the fixed electrode 30 and in the other surface 620b opposing the one surface 620a on the side facing the fixed electrode 30. The concave portion 64 provided along the node of vibration 30c in the one surface 620a of the vibrating portion 620 is arranged so as to be opened toward the direction in which the fixed electrode 30 is provided. The concave portion 64 provided along the node of vibration 30c in the other surface 620b of the vibrating portion 620 is arranged so as to be opened toward the opposite direction from the direction in which the fixed electrode 30 is provided.

In the MEMS vibrator 1e, when flexure occurs in the vibrating portion 620, stress for the flexure is likely to occur in the second direction intersecting the first direction, compared to the first direction. Moreover, the concave portions 64 provided as the functional portion 60 act as a rib, so that the torsion of the vibrating portion 620 occurring in the second direction can be suppressed.

Hence, it is possible to obtain the MEMS vibrator 1e with which, when the vibrating portion 620 vibrates, the following vibration mode is obtained: the node of vibration 30c is positioned in the first direction in which the support portion 40 is extended, the wave of vibration propagates in the second direction intersecting the first direction, and the antinode of vibration 30p is formed in the third direction orthogonal to the first direction and the second direction.

### Modified Example 6

FIG. 10F is a cross-sectional view schematically showing a cross section of a vibrating portion of a MEMS vibrator according to Modified Example 6.

In the MEMS vibrator 1f according to Modified Example 6, the configuration of the functional portion 60 as a portion having a different thickness in the vibrating portion 720 differs from the vibrating portion 20 of the MEMS vibrator 1 described in the first embodiment.

As shown in FIG. 10F, the functional portion 60 of the vibrating portion 720 of the MEMS vibrator 1f is provided along the node of vibration 30c where the support portion 40 extends.

The functional portion 60 is configured to include a pair of concave portions 66 provided, so as to oppose each other, in one surface 720a of the vibrating portion 720 facing the fixed electrode 30 and in the other surface 720b opposing the one surface 720a on the side facing the fixed electrode 30. The bottom surface of the concave portion 66 has a spherical shape.

The concave portion 66 provided along the node of vibration 30c in the one surface 720a of the vibrating portion 720 is arranged so as to be opened toward the direction in which the fixed electrode 30 is provided. The concave portion 66 provided along the node of vibration 30c in the other surface 720b of the vibrating portion 720 is arranged so as to be opened toward the opposite direction from the direction in which the fixed electrode 30 is provided.

In the MEMS vibrator 1f, when flexure occurs in the vibrating portion 720, stress for the flexure is likely to occur in the second direction intersecting the first direction, compared to the first direction. Moreover, the torsion of the vibrating portion 720 occurring in the second direction can be suppressed by the concave portions 66 provided as the functional portion 60. Moreover, since the bottom surface of the concave portion 66 has a spherical shape, a concentration of stress on the concave portion 66 can be relieved when flexure occurs in the vibrating portion 720.

Hence, it is possible to obtain the MEMS vibrator 1f with which, when the vibrating portion 720 vibrates, the following vibration mode is obtained: the node of vibration 30c is positioned in the first direction in which the support portion 40 is extended, the wave of vibration propagates in the second direction intersecting the first direction, and the antinode of vibration 30p is formed in the third direction orthogonal to the first direction and the second direction.

### Modified Example 7

FIG. 10G is a cross-sectional view schematically showing a cross section of a vibrating portion of a MEMS vibrator according to Modified Example 7.

In the MEMS vibrator 1g according to Modified Example 7, the configuration of the functional portion 60 as a portion having a different thickness in the vibrating portion 820 differs from the vibrating portion 20 of the MEMS vibrator 1 described in the first embodiment.

As shown in FIG. 10G, the functional portion 60 provided in the vibrating portion 820 of the MEMS vibrator 1g is provided along the first direction in which the node of vibration 30c of the vibrating portion 820 extends. Moreover, in the vibrating portion 820, the functional portion 60 is extended along the first direction in which the antinode of vibration 30p extends. The functional portion 60 is configured to include a pair of concave portions 64 provided, so as to oppose each other, in one surface 820a of the vibrating portion 820 facing the fixed electrode 30 and in the other surface 820b opposing the one surface 820a on the side facing the fixed electrode 30. The concave portion 64 provided along the node of vibration 30c in the one surface 820a of the vibrating portion 820 is arranged so as to be opened toward the direction in which the fixed electrode 30 is provided. The concave portion 64 provided along the node of vibration 30c in the other surface 820b of the vibrating portion 820 is arranged so as to be opened toward the opposite direction from the direction in which the fixed electrode 30 is provided.

In the MEMS vibrator 1g, when flexure occurs in the vibrating portion 820, stress for the flexure is likely to occur in the second direction intersecting the first direction, compared to the first direction. Moreover, the concave portions 64 provided as the functional portion 60 act as a rib, so that the torsion of the vibrating portion 820 occurring in the second direction can be suppressed.

Hence, it is possible to obtain the MEMS vibrator 1g with which, when the vibrating portion 820 vibrates, the following vibration mode is obtained: the node of vibration 30c is positioned in the first direction in which the support portion 40 is extended, the wave of vibration propagates in the second direction intersecting the first direction, and the antinode of vibration 30p is formed in the third direction orthogonal to the first direction and the second direction.

### Embodiments

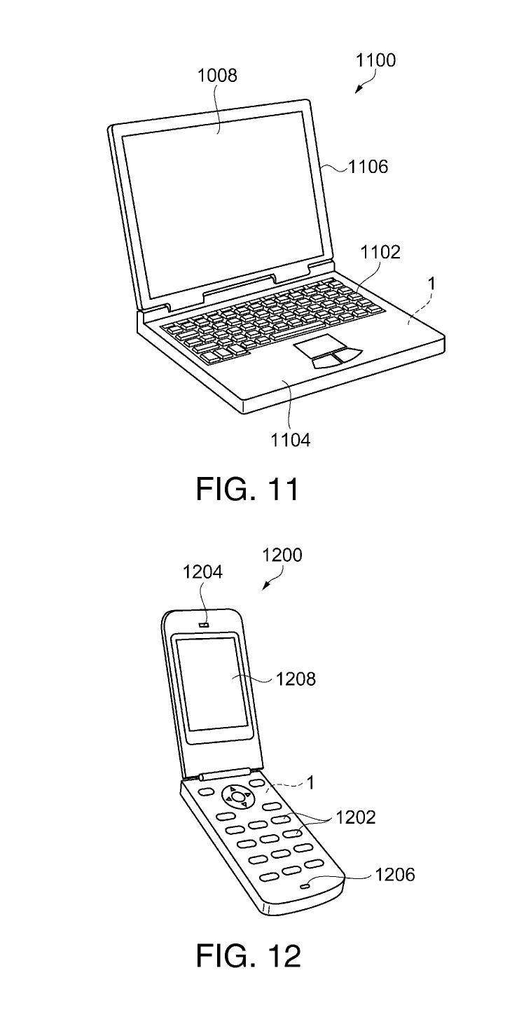

Embodiments to which the MEMS vibrator 1 or any of the MEMS vibrators 1a to 1g (hereinafter referred to collectively as the MEMS vibrator 1) according to the first embodiment of the invention is applied will be described with reference to FIGS. 11 to 14.

### Electronic Apparatuses

Electronic apparatuses to which the MEMS vibrator 1 according to the first embodiment of the invention is applied will be described with reference to FIGS. 11 to 13.

FIG. 11 is a perspective view schematically showing the configuration of a notebook (or mobile) personal computer as an electronic apparatus including the MEMS vibrator according to the first embodiment of the invention. In the drawing, the notebook personal computer 1100 is composed of a main body portion 1104 including a keyboard 1102 and a display unit 1106 including a display portion 1008. The display unit 1106 is rotationally movably supported relative to the main body portion 1104 via a hinge structure portion. For example, in the notebook personal computer 1100, the MEMS vibrator 1 that functions as an acceleration sensor or the like for detecting acceleration or the like applied to the notebook personal computer 1100 and displaying the acceleration or the like on the display unit 1106 is incorporated.

FIG. 12 is a perspective view schematically showing the configuration of a mobile phone (including a PHS) as an electronic apparatus including the MEMS vibrator according to the first embodiment of the invention. In the drawing, the mobile phone 1200 includes a plurality of operation buttons 1202, an earpiece 1204, and a mouthpiece 1206. A display portion 1208 is arranged between the operation buttons 1202 and the earpiece 1204. In the mobile phone 1200, the MEMS vibrator 1 that functions as an acceleration sensor or the like for detecting acceleration or the like applied to the mobile phone 1200 and assisting the operation of the mobile phone 1200 is incorporated.

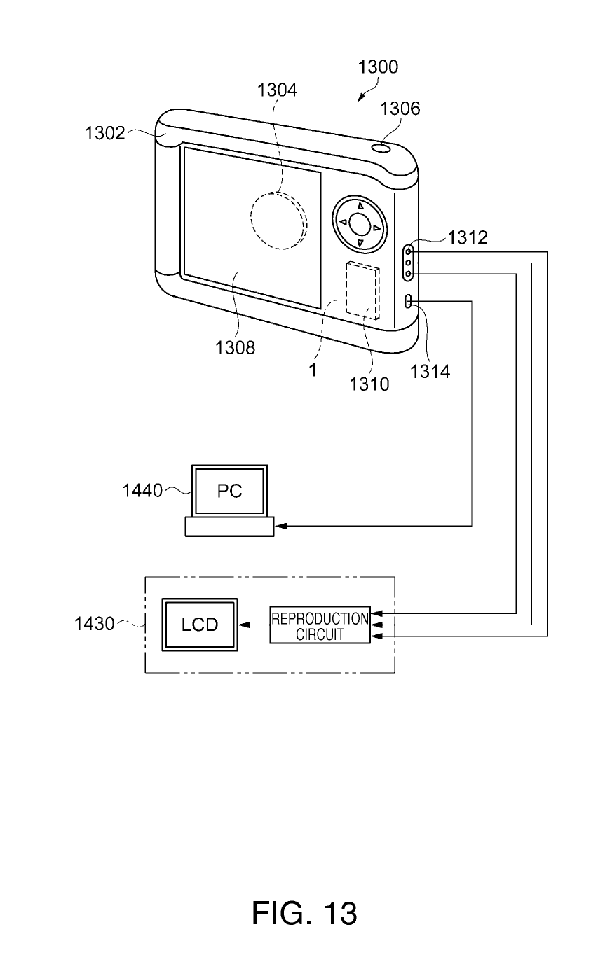

FIG. 13 is a perspective view schematically showing the configuration of a digital still camera as an electronic apparatus including the MEMS vibrator according to the first embodiment of the invention. In the drawing, connections with external apparatuses are also shown in a simplified manner. Here, usual cameras expose a silver halide photographic film with an optical image of a subject, whereas the digital still camera 1300 photoelectrically converts an optical image of a subject with an imaging element such as a charge coupled device (CCD) to generate imaging signals (image signals).

A display portion 1308 is provided on the back surface of a case (body) 1302 in the digital still camera 1300 and configured to perform display based on the imaging signals generated by the CCD. The display portion 1308 functions as a finder that displays a subject as an electronic image. Moreover, on the front side (the rear side in the drawing) of the case 1302, a light receiving unit 1304 including an optical lens (imaging optical system) and the CCD is provided.

When a photographer confirms a subject image displayed on the display portion 1308 and presses down a shutter button 1306, imaging signals of the CCD at the time are transferred to and stored in a memory 1310. Moreover, in the digital still camera 1300, a video signal output terminal 1312 and a data communication input/output terminal 1314 are provided on the side surface of the case 1302. Then, as shown in the drawing, a liquid crystal display 1430 and a personal computer 1440 are connected as necessary to the video signal output terminal 1312 and the data communication input/output terminal 1314, respectively. Further, the imaging signals stored in the memory 1310 are output to the liquid crystal display 1430 or the personal computer 1440 by a predetermined operation. In the digital still camera 1300, for activating a function of protecting the digital still camera 1300 from a fall, the MEMS vibrator 1 that functions as an acceleration sensor detecting acceleration caused by the fall is incorporated.

In addition to the personal computer (mobile personal computer) in FIG. 11, the mobile phone in FIG. 12, and the digital still camera in FIG. 13, the MEMS vibrator 1 according to the first embodiment of the invention can be applied to electronic apparatuses such as, for example, inkjet ejection apparatuses (for example, inkjet printers), television sets, video camcorders, video tape recorders, car navigation systems, pagers, electronic notebooks (including those with communication function), electronic dictionaries, calculators, electronic gaming machines, word processors, workstations, videophones, surveillance television monitors, electronic binoculars, POS terminals, medical equipment (for example, electronic thermometers, sphygmomanometers, blood glucose meters, electrocardiogram measuring systems, ultrasonic diagnosis apparatuses, and electronic endoscopes), fishfinders, various kinds of measuring instrument, indicators (for example, indicators used in vehicles, aircraft, and ships), and flight simulators.

### Moving Object

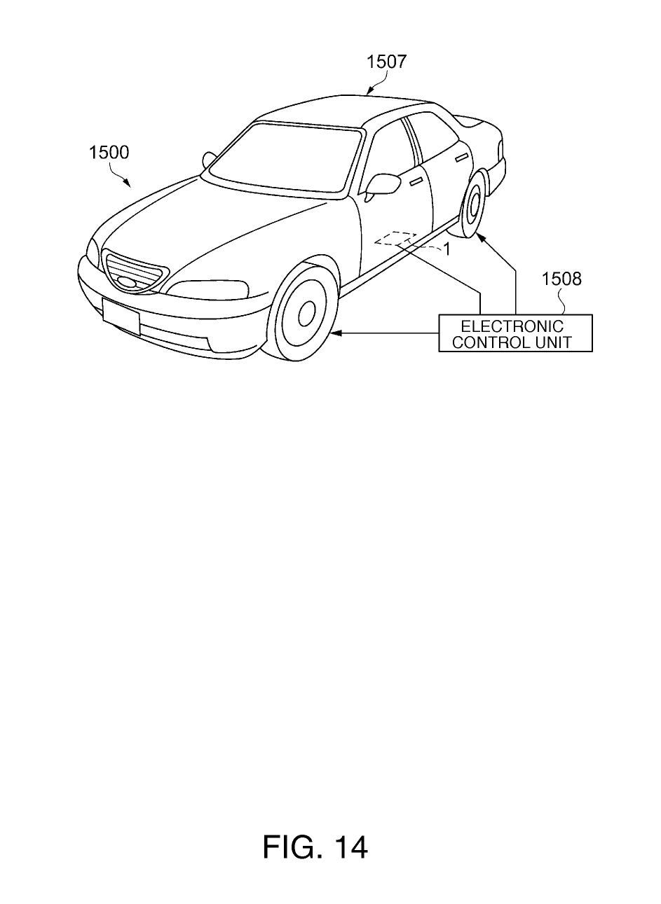

FIG. 14 is a perspective view schematically showing an automobile as an example of a moving object. In the automobile 1500, the MEMS vibrator 1 that functions as an acceleration sensor is mounted in various kinds of control units. For example, as shown in FIG. 14, in the automobile 1500 as a moving object, an electronic control unit (ECU) 1508 that incorporates therein the MEMS vibrator 1 detecting the acceleration of the automobile 1500 and controls the output of an engine is mounted in a car body 1507. The acceleration is detected to control the engine to have a proper output according to the attitude of the car body 1507, so that it is possible to obtain the automobile 1500 as an efficient moving object in which the consumption of fuel or the like is suppressed.

In addition, the MEMS vibrator 1 can be widely applied to car body attitude control units, anti-lock brake systems (ABSs), air bags, and tire pressure monitoring systems (TPMSs).

The entire disclosure of Japanese Patent Application No. 2013-087207, filed Apr. 18, 2013 is expressly incorporated by reference herein.

What is claimed is:

1. A MEMS vibrator comprising:
a vibrating portion;
an electrode portion provided to face the vibrating portion with a gap therebetween; and
a support portion extended in a first direction from the vibrating portion, wherein
the vibrating portion includes a functional portion including a concave portion or a convex portion in a cross section viewed from the first direction.

2. A MEMS vibrator comprising:
a vibrating portion;
an electrode portion provided to face the vibrating portion with a gap therebetween; and
a support portion extended in a first direction from the vibrating portion, wherein
the vibrating portion includes a functional portion having a different thickness viewed from the first direction.

3. The MEMS vibrator according to claim 1, wherein
a plurality of the functional portions are arranged in parallel along a second direction intersecting the first direction.

4. The MEMS vibrator according to claim 2, wherein
a plurality of the functional portions are arranged in parallel along a second direction intersecting the first direction.

5. The MEMS vibrator according to claim 1, wherein
the functional portion is provided with a convex portion on one surface of the vibrating portion facing the electrode portion, and provided with a concave portion opposing the convex portion in the other surface of the vibrating portion opposing the one surface.

6. The MEMS vibrator according to claim 2, wherein
the functional portion is provided with a convex portion on one surface of the vibrating portion facing the electrode portion, and provided with a concave portion opposing the convex portion in the other surface of the vibrating portion opposing the one surface.

7. The MEMS vibrator according to claim 1, wherein
the functional portion is provided with a concave portion in one surface of the vibrating portion facing the electrode portion, and provided with a convex portion opposing the concave portion on the other surface of the vibrating portion opposing the one surface.

8. The MEMS vibrator according to claim 2, wherein
the functional portion is provided with a concave portion in one surface of the vibrating portion facing the electrode portion, and provided with a convex portion opposing the concave portion on the other surface of the vibrating portion opposing the one surface.

9. The MEMS vibrator according to claim 1, wherein
the functional portion is provided with a first convex portion on one surface of the vibrating portion facing the electrode portion, and provided with a second convex portion opposing the first convex portion on the other surface of the vibrating portion opposing the one surface.

10. The MEMS vibrator according to claim 2, wherein
the functional portion is provided with a first convex portion on one surface of the vibrating portion facing the electrode portion, and provided with a second convex portion opposing the first convex portion on the other surface of the vibrating portion opposing the one surface.

11. The MEMS vibrator according to claim 1, wherein
the functional portion is provided with a first concave portion in one surface of the vibrating portion facing the electrode portion, and provided with a second concave portion opposing the first concave portion in the other surface of the vibrating portion opposing the one surface.

12. The MEMS vibrator according to claim 2, wherein
the functional portion is provided with a first concave portion in one surface of the vibrating portion facing the electrode portion, and provided with a second concave portion opposing the first concave portion in the other surface of the vibrating portion opposing the one surface.

13. The MEMS vibrator according to claim 1, wherein
the functional portion is extended in the first direction from one outer edge of the vibrating portion toward the other outer edge as an opposite side, the outer edges extending in the second direction intersecting the first direction.

14. The MEMS vibrator according to claim 2, wherein
the functional portion is extended in the first direction from one outer edge of the vibrating portion toward the other outer edge as an opposite side, the outer edges extending in the second direction intersecting the first direction.

15. A MEMS vibrator comprising:
a vibrating portion;
an electrode portion provided to face the vibrating portion with a gap therebetween; and
a support portion extended in a first direction from the vibrating portion, wherein
the vibrating portion is provided with a functional portion on both end surfaces in a second direction intersecting the first direction, the functional portion including a groove portion extending in the first direction.

16. An electronic apparatus comprising the MEMS vibrator according to claim 1.

17. An electronic apparatus comprising the MEMS vibrator according to claim 2.

18. A moving object comprising the MEMS vibrator according to claim 1.

19. A moving object comprising the MEMS vibrator according to claim 2.
